(19) United States
(12) Patent Application Publication
(10) Pub. No.: US 2022/0325861 A1
(43) Pub. Date: Oct. 13, 2022

(54) SYSTEMS AND METHODS FOR FILM-READY SOLAR SIGN

(71) Applicant: OptoGlo, Inc., Leominster, MA (US)

(72) Inventor: Kevin Donahue, Harvard, MA (US)

(73) Assignee: OptoGlo, Inc., Leominster, MA (US)

(21) Appl. No.: 17/718,212

(22) Filed: Apr. 11, 2022

Related U.S. Application Data
(60) Provisional application No. 63/173,801, filed on Apr. 12, 2021.

(51) Int. Cl. F21S 9/03; F21V 8/00; F21V 21/10; F21V 21/08; F21V 21/02; H02S 20/30; H02S 30/10; H02S 40/22; G09F 13/04

(52) U.S. Cl. CPC F21S 9/037; G02B 6/0051; G02B 6/0088; F21V 21/10; F21V 21/08; F21V 21/02; H02S 20/30; H02S 30/10; H02S 40/22; G09F 13/0409; G09F 13/0413

(57) ABSTRACT

The systems and methods of the present disclosure provide film-ready solar signs and assemblies for installations of solar signs.

### RELATED APPLICATIONS

This patent application claims the benefit of and priority to U.S. Provisional Patent Application No. 63/173,801 titled “SYSTEMS AND METHODS FOR FILM-READY SOLAR SIGN,” and filed Apr. 12, 2021, the contents of all of which are hereby incorporated herein by reference in its entirety for all purposes

### BACKGROUND

Graphics can be illuminated by lighting sources. However, it can be challenging to properly illuminate graphics uniformly.

### SUMMARY

Film-ready solar signs as described herein can be used for applications such as real estate signs, yard signs, wayward signs, directional signs, wall signs, and vehicle signs. The signs can include a diffusion film through which sunlight traverses to a solar film or panel, which can generate electron flow to be stored by a battery. The energy stored by the battery can be used to power lighting elements at night, such as light emitting diodes (LEDs).

Installation hardware can be used to install the signs in a manner that allows for long-term, reliable use of the signs as well as useful viewing properties for the signs. The installation hardware can include, for example, A-frames, metal posts, ground mounts, clips, brackets, and fasteners. The installation hardware can orient the signs so that the signs are tilted enough to receive sufficient solar energy for reliable, long-term use (e.g. ability to stay illuminated throughout the night), yet the signs can still appear vertical. The installation hardware can be used to easily install the signs, such as through the use of hammers and/or fasteners, such as screws. The signs can be replaceably received by the installation hardware to allow for signs to be replaced or modified. Multiple signs can be received by the installation hardware on multiple sides of the installation hardware. The signs can be film-ready, such as by being provided as a module that can be coupled with the installation hardware and which can receive the diffusion film (which can have printed material, such as printed ink, printed on the diffusion film). For example, the signs or the installation hardware can include receiving members to receive the diffusion film on the signs, or an adhesive can be used to overlay the film on the signs.

At least one aspect of the present disclosure is directed to a film-ready solar sign. The solar sign can include a backlight including a light guide and a solar panel coupled to the light guide, a printable diffusion film placeable on the backlight, and a mount. The solar panel receives light through the light guide. The mount is configured to orient the backlight at an angle relative to ground, the angle is (1) greater than or equal to a first value corresponding to a minimum amount of solar energy from the light received by the solar panel through the diffusion film and the light guide and (2) less than or equal to a second value at which an appearance of information printed on the diffusion film satisfies a criteria of verticality.

In some implementations, the criteria of verticality corresponds to a first distance from a top of backlight to a point facing the backlight and a second distance from a bottom of the backlight to the point.

In some implementations, the solar sign assembly includes at least one receiver that slidably receives the backlight.

In some implementations, the mount includes a metal post.

In some implementations, the mount includes a first plate configured to be attached to a wall, a second plate configured to receive the backlight, and a plurality of flanges configured to orient the second plate at the angle.

In some implementations, the mount includes at least one of an A-frame, a post, a universal mount, or an artwork frame.

At least one other aspect of the present disclosure is directed to a solar sign frame. The solar sign frame can include a solar-powered light panel, a printable diffusion film placeable on the light panel, and a mount configured to orient the backlight at no more than a predetermined angle relative to vertical.

In some implementations, the mount includes a plurality of beams configured to receive the light panel and orient the light panel at the angle.

In some implementations, the solar sign frame includes at least one receiver that slidably receives the light panel.

In some implementations, the solar sign frame includes a metal post configured to be driven into a ground surface.

In some implementations, the mount includes a first plate configured to be attached to a wall, a second plate configured to receive the backlight, and a plurality of flanges configured to orient the second plate at the angle.

In some implementations, the mount includes at least one of an A-frame, a post, a universal mount, or an artwork frame.

At least one other aspect of the present disclosure is directed to a portable solar-powered sign. The sign can include a backlight including a light guide and a solar panel, a diffusion film having printed ink and placeable on the backlight, and a mount. The solar panel is coupled to the light guide and receives light through the light guide. The mount is configured to orient the backlight at an angle relative to ground such that a visibility of the diffusion film satisfies a visibility criteria during a day condition and a night condition and an amount solar energy received during the day condition satisfies a solar energy criteria.

In some implementations, the mount includes a plurality of beams configured to receive the light panel and orient the light panel at the angle.

In some implementations, the sign includes at least one receiver that slidably receives the light panel.

In some implementations, the mount includes a metal post.

In some implementations, the mount includes a first plate configured to be attached to a wall, a second plate configured to receive the backlight, and a plurality of flanges configured to orient the second plate at the angle.

In some implementations, the mount includes at least one of an A-frame, a post, a universal mount, or an artwork frame.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the invention can be combined with other aspects. Aspects can be implemented in any convenient form.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. The foregoing and other objects, aspects, features, and advantages of the disclosure will become more apparent and better understood by referring to the following description taken in conjunction with the accompanying drawings, in which:

FIG. 1A illustrates an exploded view of an example solar sign having a printable surface and a housing, in accordance with one or more implementations;

FIG. 1B illustrates a cross-sectional view of the example solar sign of FIG. 1A, in accordance with one or more implementations;

FIG. 2A illustrates an exploded view of an example printable solar sign sheet, in accordance with one or more implementations;

FIG. 2B illustrates a cross-sectional view of the example printable solar sign sheet shown in FIG. 2A, in accordance with one or more implementations;

FIG. 2C illustrates a front view of the example printable solar sign sheet shown in FIGS. 2A and 2B, in accordance with one or more implementations; and

FIG. 2D illustrates a side view of the example printable solar sign shown in FIGS. 2A, 2B, and 2C, in accordance with one or more implementations.

FIG. 3 illustrates a schematic diagram of an example sign installed on the ground using an A-frame, in accordance with one or more implementations.

FIG. 4A illustrates an exploded view of an example solar sign assembly using an A-frame, in accordance with one or more implementations.

FIG. 4B illustrates a side view of the example solar sign assembly shown in FIG. 4A, in accordance with one or more implementations.

FIG. 4C illustrates a front view of the example solar sign assembly shown in FIGS. 4A and 4B, in accordance with one or more implementations.

FIG. 4D illustrates a side view of the example solar sign assembly shown in FIGS. 4A, 4B, and 4C, in accordance with one or more implementations.

FIG. 5A illustrates an exploded view of an example solar sign assembly using a ground mount, in accordance with one or more implementations.

FIG. 5B illustrates a front view of the example solar sign assembly shown in FIG. 5A, in accordance with one or more implementations.

FIG. 5C illustrates a side view of the example solar sign assembly shown in FIGS. 5A and 5B, in accordance with one or more implementations.

FIG. 6A illustrates an exploded view of an example solar sign assembly using a universal mount, in accordance with one or more implementations.

FIG. 6B illustrates a side view of the example solar sign assembly shown in FIG. 6A, in accordance with one or more implementations.

FIG. 6C illustrates a front view of the example solar sign assembly shown in FIGS. 6A and 6B, in accordance with one or more implementations.

FIG. 6D illustrates a side view of the example solar sign assembly shown in FIGS. 6A, 6B, and 6C, in accordance with one or more implementations.

FIG. 7A illustrates an exploded view of an example solar sign assembly using a replaceable sign, in accordance with one or more implementations.

FIG. 7B illustrates a front view of the example solar sign assembly shown in FIG. 7A, in accordance with one or more implementations.

FIG. 7C illustrates a side view of the example solar sign assembly shown in FIGS. 7A and 7B, in accordance with one or more implementations.

### DETAILED DESCRIPTION

The various concepts introduced above and discussed in greater detail below may be implemented in any of numerous ways, as the described concepts are not limited to any particular manner of implementation. Examples of specific implementations and applications are provided primarily for illustrative purposes.

Solar-powered illuminated signs are gaining popularity. In general, conventional signs can be used for traffic management and can include multiple externally-connected components. Common solar signs can include stop signs with a border composed of red light-emitting diodes and a post capped with a mounted solar panel. However, these signs are cumbersome, expensive and from a design standpoint, ugly. The techniques described in the present disclosure provide a printable sheet, with no external components. The sheet can be illuminated internally at night, or during dark conditions. The techniques described herein provide a thin (e.g., less than 5 mm thick, etc.) board with a print ready surface. The print-ready surface can be printed upon using a printer, such as an inkjet printer or a large-format latex inkjet printer.

The printable illuminated sign sheet described herein can include a stack of thin, functional layers. The layer exposed to an external can include a diffusion film with micron-scale surface features that facilitate extreme light turning or diffusion. As a result, the surface of the sheet can appear white, when in actuality the sheet can transmit more than 80% of the incident light into the underlying layers. Below the print-ready diffusion surface sits a thin light guide plate (LGP) that emits uniform lighting produced by light emission from edge mounted light sources, such as light-emitting diodes (LEDs). A solar panel or film can be coupled to the light guide plate, and can be electrically coupled to an electronics module. The electronics module can be in the sign sheet on same layer as, or on a layer proximate to, the solar panel or film in the light illuminated sign sheet.

Sunlight, or another external light, can traverse the diffusion surface of the printable layer and pass through the optically clear LGP and finally contact the underlying solar film or panel, which in turn generates electron flow. These electrons are subsequently forwarded to the internal battery to be stored as power for night illumination.

The signs, such as the printable sign sheet, can be mounted to ground, a wall, a vehicle, to a building structure (e.g., to be implemented as a wayward or directional sign, such as for commercial or retail uses), or various other components using installation hardware as described herein. The installation hardware can replaceably receive the signs as a module or overlay. The installation hardware can include A-frames, ground mounts, posts, or clips. The installation hardware can orient the sign at an angle that is greater than a first angle corresponding to a target amount of solar energy to be received by the solar panel or film, and less than a second angle corresponding to a verticality threshold for the sign. The installation hardware can include manually manipulable components, such as thumb screws and nuts, to allow for replaceable installation of signs and overlays.

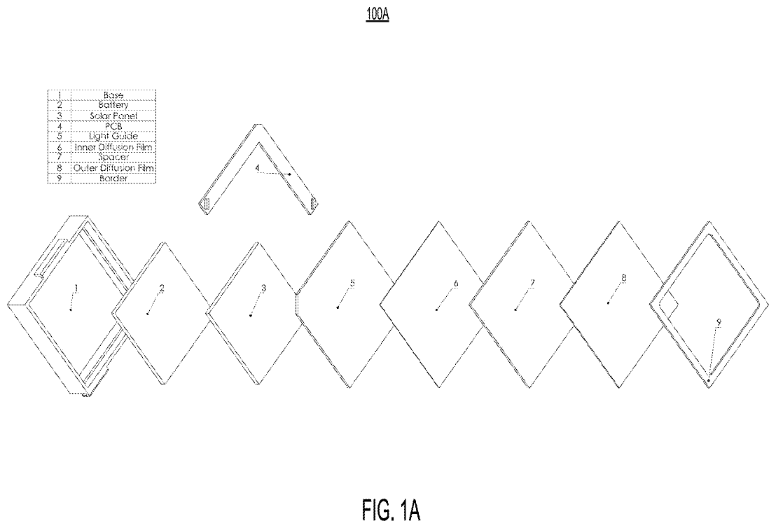

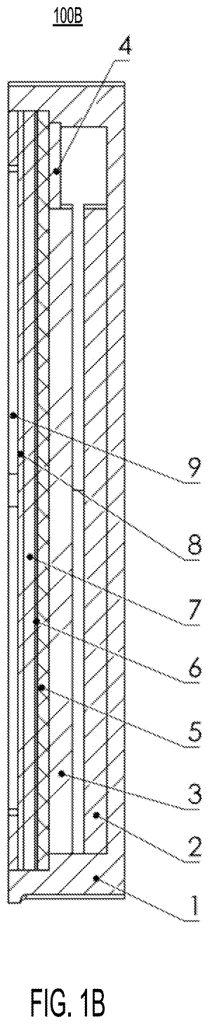

Referring now to FIG. 1A illustrated is an exploded view 100A of an example solar sign having a printable surface and a housing, in accordance with one or more implementations. The solar sign can include at least one base 1 (sometimes referred to as a “housing 1”), a battery 2, a solar panel 3, a printed circuit board (PCB) 4, a light guide 5, an inner diffusion film 6, a spacer 7, an outer diffusion film 8, and a border 9. As described herein, each of the components of the solar sign depicted in FIG. 1A can form a portion, or the entirety of, a layer of the solar sign. The layers can be stacked and coupled to one another, for example, using an adhesive or mechanical coupling or connector. In some implementations, the layers can be coupled to one another via mechanical force.

The base 1 can be a waterproof container that contains each of the layers depicted in FIG. 1A. The base 1 can prevent unwanted materials (e.g., water, dust, debris, etc.) from entering the sign and causing electrical issues or blocking light paths. The base 1 can be constructed from a polymer material, a metal material, or a composite material. As shown in the view 100A, each of the components of the solar sign (e.g., the battery 2, the solar panel 3, the printed circuit board (PCB) 4, the light guide 5, the inner diffusion film 6, the spacer 7, the outer diffusion film 8, the border 9, etc.) can be positioned in or coupled to the housing, for example, in one or more layers of a stack. The components can be coupled to one another, for example, by one or more mechanical features (e.g., each of the components can be manufactured to fit together tightly within the base 1, etc.), such as connectors, fasteners, or other mechanical coupling features. In some implementations, one or more of the components of the solar sign can be coupled to one another via an adhesive or other non-mechanical coupling agent. In some implementations, the adhesive can be an optically transparent adhesive. The outer portion of the base 1 can be coupled to the supporting hardware, such as an A-frame. In some implementations, the base 1 can include one or more connectors to couple to other solar signs or other support features.

The battery 2 can be a thin, flat battery that can provide electrical power to one or more of the electronic components of the solar sign, as described herein. The battery 2 can be a re-chargeable battery, such as a lithium-ion battery, a lithium-polymer battery, a nickel-cadmium battery, or another type of high-density re-chargeable battery with a thin form factor. The battery 2 can receive electric power from the solar panel 3, for example, via charging circuitry present on the PCB 4. The battery 2 can discharge electrical energy through one or more light sources, such as light-emitting diodes, that are present in the solar sign. In some implementations, the battery 2 can be positioned in the solar sign such that it is easily removable. In such implementations, the components of the solar sign can fit together such that the solar sign can be disassembled, and the battery 2 can be replaced.

The solar panel 3 can be coupled to the battery 2, and the light guide 5, and can absorb light that passes through the outer diffusion film 8, the spacer 7, and the inner diffusion film 6, and the light guide 5. The solar panel 3 can provide electric power to the other components of the solar sign described herein. Light emitted from an external light source (e.g., the sun, etc.) can pass through the layers of the diffusion film, the spacer, and the light guide 5, and contact the surface of the solar panel 3. Photons in the light can be absorbed by the solar panel 3 and converted into an electron flow that is stored in the battery 2 (e.g., via power circuitry on the PCB 4, etc.). The battery 2 can store a charge over the course of a day (e.g., via the solar panel 3 absorbing energy from an external light source, etc.). Then, in circumstances of low light (e.g., each evening if the solar sign is positioned outside, etc.), the solar panel 3 can generate a decreased electron flow (e.g., a decreased voltage from what was produced during periods of high external light, etc.) The solar panel 3 can be any sort of photovoltaic cell or photovoltaic film having a thin form factor. The solar panel 3 can be constructed from semiconducting materials, such as doped silicon.

The PCB 4 can include electronics, such as power electronics that can control the flow of electrons output by the solar panel 3. As described herein above, the PCB 4 can be electrically coupled to the solar panel 3 via one or more electrical connections (not shown). The PCB 4 can include one or more voltage sensors that can monitor voltage signals produced by the solar panel 3. In some implementations, the PCB 4 can include one or more voltage sensors that monitor the voltage level of the battery. For example, each of the voltage sensors can output a signal (e.g., an electrical signal, etc.) that indicates an amount of voltage generated by the solar panel 3 or the battery 2. The signals can be received, for example, by a controller on the PCB 4.

The PCB 4 can include one or more light sources that can illuminate the solar sign via the light guide 5 (described in further detail herein). The light sources can be any sort of light source that can emit light in response to receiving electric energy. The light sources can be electrically coupled to and receive electric power from the battery, for example, via power circuitry (e.g., voltage converters, etc.) on the PCB 4. The light sources can emit light with an intensity that is proportional to the amount of electric power received from the power circuitry. Thus, the power circuitry can control the amount of electric power provided to the light sources, and thus the amount of light emitted by the light sources. The light sources can have a thickness that corresponds (e.g., about equal to, less than, etc.) to a thickness of the light guide 5. The light sources can be, for example, one or more LEDs or any other type of light source. The light source can be a bright source of light that uses a low amount of power.

The PCB 4 can include a controller that can monitor voltage signals produced by the voltage sensors and provide power controls to the electronic components (e.g., the light sources, the solar panel 3, etc.) of the solar sign. The controller can include at least one processor and a memory (e.g., a processing circuit, etc.). The memory can store processor-executable instructions that, when executed by processor, cause the processor to perform one or more of the operations described herein. The processor can include a microprocessor, an application-specific integrated circuit (ASIC), a field-programmable gate array (FPGA), etc., or combinations thereof. The memory can include, but is not limited to, electronic, optical, magnetic, or any other storage or transmission device capable of providing the processor with program instructions. The memory can further include a memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor can read instructions. The instructions can include code from any suitable computer programming language.

The processor of the electronics module can receive signals (e.g., via an interconnect or other communications bus, etc.) from the voltage sensors on the PCB 4 that correspond to the amount of light being received by the solar panel 3. Based on the mount of light received from the solar panel 3, the processor can provide signals to one or more switches (e.g., transistors, integrated circuits, etc.) that cause the battery 2 to provide electric power to the light sources connected to the PCB 4. For example, if the processor detects that the amount of voltage produced by the solar panel 3 has fallen below a predetermined threshold, the processor can determine that the solar sign is not properly or completely illuminated. Based on the signals from the voltage sensors, the processor can determine whether the amount of light striking the solar panel 3 represents a temporary blockage (e.g., an external light source is obscured temporarily, etc.), of the amount of light striking the solar panel 3 represents that the solar sign is now in a dark environment (e.g., it is now night time, or the solar sign has been moved to a dark room, etc.). The processor can compensate for the low light levels by transitioning form an unilluminated (e.g., the light source is not receiving power, etc.) state to an illuminated (e.g., the light source is receiving power, etc.) state. The processor can provide (e.g., via the power circuitry, transistors, switches, etc.) an amount of power that is proportional to the amount of light required to illuminate the solar sign. In some implementations, the processor can store information about the amount and the color of one or more graphical designs or printed images printed on the outer surface of the outer diffusion film 8. For darker images with more ink, the processor can provide more electric power to the light sources, thus providing more light to illuminate the darker graphic. Likewise, if a graphic on the solar sign is absent, or has light or small amounts of ink, the processor can provide slightly less electric power to the, thus providing uniform illumination for the solar sign.

The light guide 5 can be positioned adjacent to the solar panel 3, such that light passing through the light guide can strike the solar panel 3 and generate electric power. The light guide 5 can be a transparent plate of material that can both receive and guide light from one or more light sources, such as the light sources on the PCB 4 or an external light source, such as the sun. As described herein, the surface of the light guide 5 (e.g., the surface coupled to the inner diffusion film 6, etc.) can include one or more light extraction features, such as lenses or lenslets. In some implementations, the surface of the light guide 5 opposite the surface coupled to the inner diffusion film 6 can include one or more light exaction features. The light extraction features can extract a portion of the light injected into the light guide 5, such as the light emitted by the light sources on the PCB 4. The light guide 5 can guide another portion of the light injected into the light guide towards an opposite edge of the light guide 5. The light extraction features can be precisely placed across the surface of the light guide 5 in a predetermined pattern, such that light is uniformly extracted, and thus emitted, across the entire surface of the light guide 5. Thus, the light guide 5 can uniformly illuminate the other layers of the solar sign (e.g., the inner diffusion film 6, the spacer 7, the outer diffusion film 8, etc.), including any graphical designed printed on the outer diffusion film.

The light guide 5 can be optically coupled to the light sources in the solar sign. In some implementations, the light sources can be positioned within a cavity formed in the light guide 5. The light source can emit light through the cavity and into the body of the light guide 5, thereby injecting light into the light guide 5. In some implementations, the light guide 5 does not include a cavity, and instead is a uniform rectangular plate that can receive light emitted from the light source via an edge of the light guide 5. In such implementations, the light sources can be positioned external to the light guide 5 and inject light into the light guide plate via the edge. The light guide 5 can have a shape that accommodates the light sources, for example, having one or more edges or corners that are “clipped” or removed from a uniform rectangular plate, as shown in FIG. 1A.

The inner diffusion film 6 can be a sheet of partially transparent film that has a first surface coupled to a spacer 7 (e.g., which can be a transparent plastic spacer, for example, to achieve a desired structural thickness, etc.) and a second surface that is coupled to the light guide 5. The inner diffusion film 6 can be a partially transparent film that appears white, or another solid color, while still allowing an amount of light to pass through the diffusion film and into the light guide 5. For example, light emitted by an external light source (e.g., the sun, etc.) can pass through both the outer diffusion film 8, the spacer 7, and the inner diffusion film 6, striking the solar panel 3 where it is absorbed. The inner diffusion film 6 can be uniformly illuminated by the light extracted by the light extraction features of light guide 5, such that the solar sign and any graphical designs printed thereon can be illuminated in low-light environments (e.g., at night time, etc.). In some implementations, the inner diffusion film 6 can have greater than 70% angular diffusion. In some implementations, the inner diffusion film 6 can have a light transmission rate that exceeds 80%. The inner diffusion film can aid in the operation of the light guide 5, which in some implementations can provide a more uniformly distributed light pattern when exposed to air. The inner diffusion film 6 can have a rough surface, and thus when coupled to the light guide 5, the majority of the surface of the light guide 5 is exposed directly to air, because the rough surface of the inner diffusion film 6 is not uniform or perfectly flat.

The spacer 7 can be a thin, flat portion of plastic that acts as a buffer between the inner diffusion film 6 and the outer diffusion film 8. The spacer 7 can be manufactured from a transparent material, such as glass, a transparent acrylic, or another type of transparent plastic. The spacer 7 can have similar dimensions to the inner diffusion film 6 and the outer diffusion film 8. The spacer 7 can have a thickness selected to allow each of the components of the solar sign to fit together in the base 1 of the solar sign. The spacer 7 can have high transmissivity, such that light easily passes through the spacer 7. The spacer 7 can allow light diffused from the inner diffusion film 6 to pass largely uninterrupted to the outer diffusion film 8, thereby illuminating the solar sign. Likewise, the spacer 7 can receive light from an external light source (e.g., the sun, etc.) via the outer diffusion film 8, and allow the light to pass largely uninterrupted through the inner diffusion film 6, striking the solar panel 3.

The outer diffusion film 8 can be a sheet of partially transparent film that has a first surface exposed to an external environment and a second surface that is coupled to the spacer 7. The outer diffusion film 8 can include a light-turning imprinted surface (e.g., the surface facing the external environment, etc.). The outer diffusion film 8 can include a partially transparent surface that appears white, or another solid color, while still allowing an amount of light to pass through the diffusion film and into the light guide 5. Light from an external light source (e.g., the sun, etc.) can pass through the outer diffusion film 8, the spacer 7, the inner diffusion film 6, and the light guide 5, striking the solar panel 3 where it is absorbed. The outer diffusion film 8 can be a printable film, such that the outer diffusion film 8 can be made from a material to which printer ink can be directly applied. Thus, in some implementations, the solar sign can be passed through a printer, such as a wide format inkjet printer, which can print ink directly onto the outer diffusion film 8 of the solar sign. The solar sign can be placed on or coupled to a template that guides the solar sign through the printer to facilitate the printing process.

The outer diffusion film 8 can be printed using a latex ink, a black ink, a white ink, or any other semi-transparent ink. The outer diffusion film 8 can be uniformly illuminated by the light extracted by the light extraction features of light guide 5, such that the solar sign and any graphical designs printed thereon can be illuminated in low-light environments (e.g., at night time, etc.). In some implementations, and as described herein above, the outer diffusion film 8 can be coupled to an overlay film such that the illuminated outer diffusion film 8 provides uniform illumination through the overlay film. In some implementations, the outer diffusion film 8 can be easily removable and replaceable from the base 1. Thus, different designs for the solar sign can easily be changed by exchanging the outer diffusion films 8 having graphical designs printed thereon.

The border 9 can provide a weather-proof border for the exposed edges of the solar sign, surrounding the outer diffusion film 8. As shown, the outer diffusion film 8 can be exposed to the external environment through the large opening in the border 9. The border 9 can be manufactured from a material similar to that used to manufacture the base 1. The border 9 can be coupled to the border 9 to create a weather-proof seal, thereby preventing water, dust, or other debris from interfering with the internals of the solar sign. In some implementations, the border 9 can be removable, such that the outer diffusion film 8 can be easily removed and replaced. This can allow for different designs to be displayed on the same sign by exchanging different outer diffusion films 8 having different designs printed thereon. In some implementations, the base 1 can include one or more brackets or connectors that couple the solar sign to a frame (not pictured). The frame can position the printable solar sign at a predetermined angle from a light source, such as the sun. In doing so, the frame can position the solar sign such that the sign appears flat to a viewer (e.g., completely upright), while still absorbing a large percentage of light emitted by an external light source.

Referring now to FIG. 1B, illustrated is a cross-sectional view 100B of the example solar sign shown in FIG. 1A, in accordance with one or more implementations. As shown in the view 100B, each of the layers in the solar sign can be pressed against one another firmly, such that they are fixed in place in the base 1 of the solar sign. Also as shown, each of the components can fit within the base 1 such that the components are coupled to the base 1, for example, via mechanical or frictional force. In some implementations, an adhesive can be disposed between one or more of the layers of the solar sign. In some implementations, the adhesive can be an optically transparent adhesive with a similar index of refraction to other components of the solar sign (e.g., the light guide 5, etc.). Each of the components of the solar sign can be placed in the base in a particular order. As shown, the base 1 can form a housing for the sign, and can include one or more attachment or guiding features (e.g., grooves, slots, etc.) into which the other components of the solar sign can fit or connect.

The battery 2 can first be positioned near the bottom of the base 1. In some implementations, the battery 2 can fit into one or more slots, grooves, or recessed portions of the base 1. Next, the solar panel 3 can be positioned top of, or adjacent to, the battery 2. The solar panel 3 can be electrically coupled to the battery 2. The PCB 4 can then be positioned in the base 1 adjacent to the solar panel. The PCB 4 can be positioned such that any light sources present on the PCB 4 will be aligned with the light guide 5 when the light guide 5 is positioned in the solar sign. The light guide 5 can be positioned on top of the solar panel 3, such that light passing through the light guide 5 from an external light source can be passed to the surface of the solar panel 3. Further, the light guide 5 can be positioned in the base 1 such that an edge of the light guide 5 can receive light from a light source, such as a light source positioned on or electrically coupled to the PCB 4. In some implementations, the light source can be electrically coupled to but physically separate from the PCB 4 (e.g., on a separate circuit board module, etc.).

The inner diffusion film 6 can be positioned on top of the light guide 5, such that the light emitted from the light sources and extracted by the light extraction features on the surface of the light guide 5 is diffused through the inner diffusion film, thereby evenly illuminating the solar sign. The spacer 7 can be positioned on top of the inner diffusion film 6. As shown, the spacer can provide additional depth to the stack of functional components of the solar sign, and provide a buffer through which light from the outer diffusion film 8 can pass before reaching the inner diffusion film 6. The outer diffusion film 8 can be positioned on top of the spacer 7. As described herein above, the outer diffusion film 8 can include a printable surface exposed to the external environment. Inks such as latex inks, or other types of inks, can be printed directly onto the printable surface of the outer diffusion film 8. Finally, the border 9 can create a seal between the outer diffusion film 8 and the base 1, thereby creating a weather-proof, printable sign. It should be understood that the various signs described herein can be scaled to any appropriate dimension, and the entire sign as pictured in FIGS. 1A and 1B can have a profile passable through a printer such that the printer can print on the outer diffusion film 8.

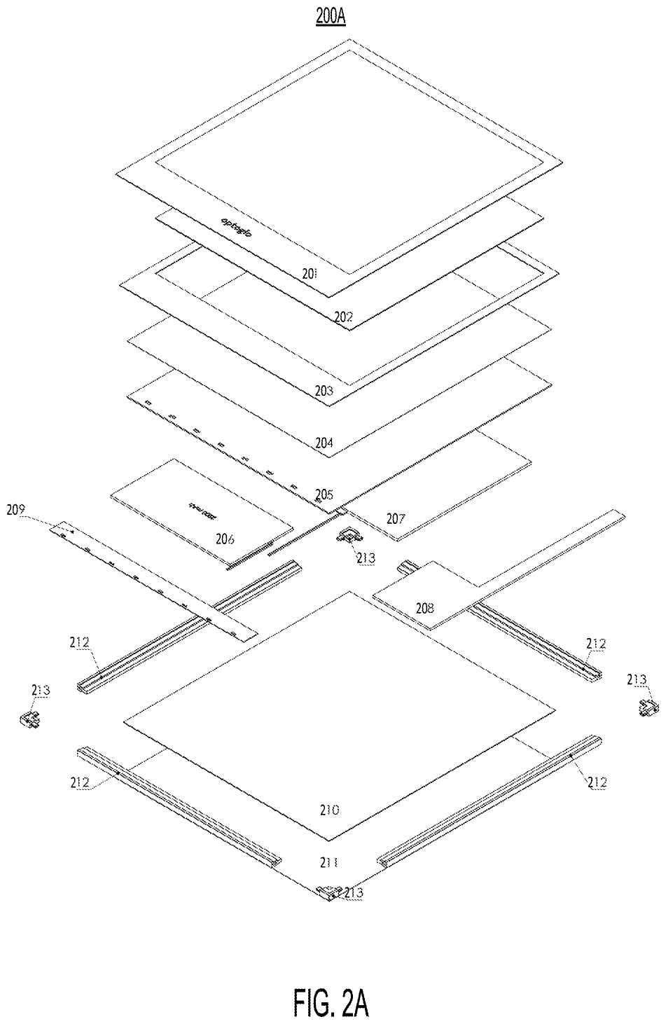

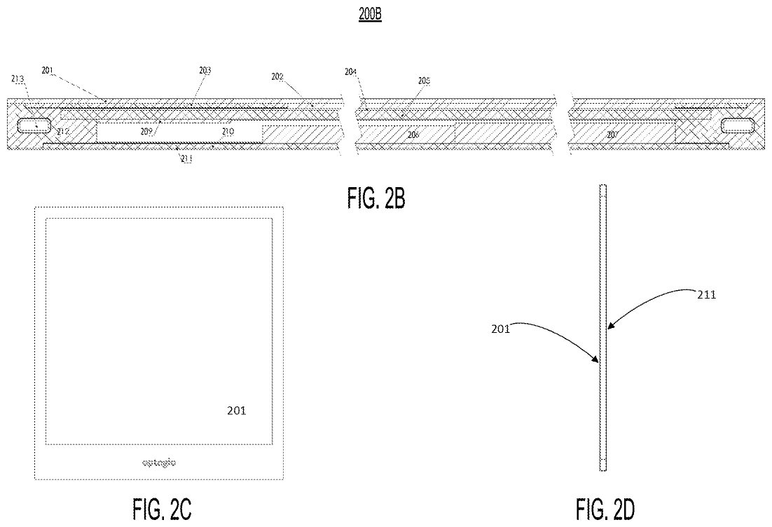

Referring now to FIG. 2A, illustrated is an exploded view 200A of an example printable solar sign sheet, in accordance with one or more implementations. The solar sign sheet shown in FIG. 2A can be a stack of functional materials, similar to the printable solar sign depicted in FIGS. 1A and 1B. The printable solar sign shown in the view 200A can include a top diffusion film 201, a spacer 202, a border 203, an inner diffusion film 204, a light guide 205, a battery 206, a solar panel 207, a filler 208, a PCB 209, a back plate 210, vinyl 211, a rail 212, and a corner piece 213. As described herein, each of the components of the solar sign depicted in FIG. 2A can form a portion, or the entirety of, a layer of the printable solar sign. The components can be coupled together, for example, via an adhesive or mechanical connectors, to form a sheet of layered, functional components. In some implementations, the layers can be coupled to one another via mechanical force such as friction.

Starting from the bottom of the stack of functional components, the corner piece 13 and the rails 212 can form portions of the edges of the solar sign. The corner piece can include one or more pegs, or other types of connectors, that allow the corner piece 213 to be connected to two of the rails 212. Four corner pieces 13 can be used in conjunction with four rails 212 to define the edges of the solar sign. The corner pieces 13 and the rails 212 can be formed from any suitable material, for example, a polymer material, a metal material, or a composite material. In some implementations, the rails can be formed from aluminum or steel. In some implementations, the corner pieces 13 and the rails 212 can include one or more grooves, slots, or recesses into which one or more of the components of the solar sign can rest or be coupled. In some implementations, the rails 212 and the corner pieces can couple to the back plate 210. The vinyl 211 can be a sheet of vinyl that covers the back portion of the rails 212, the corner pieces 213, and the back plate 210, creating a weather-proof seal across the bottom of the solar sign. The back plate 210 can be a rigid plate onto which the other layers of the solar sign are stacked or coupled. The back plate 210 can be formed from any suitable material, including plastics, metals, or composite materials.

The battery 206, the solar panel 207, the filler 208, and the PCB 209 can together form the next layer of the solar sign. The battery 206 can be similar to and include any of the structure of functionality of the battery 2 described herein above in connection with FIGS. 1A and 1B. The battery 206 can be a thin, flat battery that can provide electrical power to one or more of the electronic components of the solar sign, as described herein. The battery 206 can be a re-chargeable battery, such as a lithium-ion battery, a lithium-polymer battery, a nickel-cadmium battery, or another type of high-density re-chargeable battery with a thin form factor. In some implementations, the battery 206 can be less than about 3 millimeters thick. The battery 206 can receive electric power from the solar panel 207, for example, via charging circuitry present on the PCB 209. The battery 206 can discharge electrical energy through one or more light sources, such as light-emitting diodes, that are present in the solar sign. In some implementations, the battery 206 can be positioned in the solar sign such that it is easily removable. In such implementations, the components of the solar sign can fit together such that the solar sign can be disassembled, and the battery 206 can be replaced.

Likewise, the solar panel 207 can be similar to and include any of the structure and functionality of the solar panel 3 described herein above in connection with FIGS. 1A and 1B. The solar panel 207 can be coupled to the battery 2, and the light guide 205, and can absorb light that passes through the outer diffusion film 8, the spacer 7, and the inner diffusion film 6, and the light guide 205. The solar panel 207 can provide electric power to the other components of the solar sign described herein. Light emitted from an external light source (e.g., the sun, etc.) can pass through the layers of the diffusion film, the spacer, and the light guide 205, and contact the surface of the solar panel 207. Photons in the light can be absorbed by the solar panel 207 and converted into an electron flow that is stored in the battery 206 (e.g., via power circuitry on the PCB 4, etc.). The battery 2 can store a charge over the course of a day (e.g., via the solar panel 207 absorbing energy from an external light source, etc.). Then, in circumstances of low light (e.g., each evening if the solar sign is positioned outside, etc.), the solar panel 207 can generate a decreased electron flow (e.g., a decreased voltage from what was produced during periods of high external light, etc.) The solar panel 207 can be any sort of photovoltaic cell or photovoltaic film having a thin form factor. The solar panel 207 can be constructed from semiconducting materials, such as doped silicon.

The PCB 209 can be similar to and include any of the structure and functionality of the PCB 209 described herein in connection with FIGS. 1A and 1B. The PCB 209 can include electronics, such as power electronics that can control the flow of electrons output by the solar panel 207. As described herein above, the PCB 209 can be electrically coupled to the solar panel 207 via one or more electrical connections (not shown). The PCB 209 can include one or more voltage sensors that can monitor voltage signals produced by the solar panel 207. In some implementations, the PCB 209 can include one or more voltage sensors that monitor the voltage level of the battery 206. For example, each of the voltage sensors can output a signal (e.g., an electrical signal, etc.) that indicates an amount of voltage generated by the solar panel 207 or the battery 206. The signals can be received, for example, by a controller on the PCB 209.

The PCB 209 can include one or more light sources that can illuminate the solar sign via the light guide 205 (described in further detail herein). In some implementations, the one or more light sources can be physically separate from but still electrically coupled to the PCB 209, and any components thereof (e.g., the processor, power electronics, switches, etc.). The light sources can be any sort of light source that can emit light in response to receiving electric energy. The light sources can be electrically coupled to and receive electric power from the battery, for example, via power circuitry (e.g., voltage converters, etc.) on the PCB 209. The light sources can emit light with an intensity that is proportional to the amount of electric power received from the power circuitry. Thus, the power circuitry can control the amount of electric power provided to the light sources, and thus the amount of light emitted by the light sources. The light sources can have a thickness that corresponds (e.g., about equal to, less than, etc.) to a thickness of the light guide 205. The light sources can be, for example, one or more LEDs or any other type of light source. The light source can be a bright source of light that uses a low amount of power.

In some implementations, the PCB 209 can include one or more magnetic sensors. The magnetic sensors can be electrically coupled to one or more components of the PCB 209 (e.g., the processor, the power circuitry, etc.). The magnetic sensors can provide a signal to the components of the PCB 209 in response to sensing a magnetic field, for example, from a magnet positioned on a frame configured to hold the solar sign. The signal from the magnetic sensor can enable the use of the solar sign. Said another way, the solar sign can be used in connection with authorized frames that have magnets appropriately positioned to activate the magnetic sensors of the PCB 209. Once activated, the magnetic sensors can provide a signal that allows the sign to operate as intended (e.g., absorb light from the sun to charge the battery 206, and illuminate the sign in low-light environments, etc.). In some implementations, an electromagnetic sensor can be electrically coupled to the PCB 209. The electromagnetic radiation sensor can detect electromagnetic radiation emitted, for example, by an overlay film (e.g., similar to the top diffusion film 201, etc.) having an electromagnetic radiation source positioned thereon. Similar to the operation of the magnetic sensor, the electromagnetic radiation sensor can detect electromagnetic radiation from authorized overlay films. The electromagnetic radiation sensor can produce a signal that activates the other components of the PCB 209, allowing the solar sign to operate as intended, in response to detecting an electromagnetic radiation signal from an authorized solar sign. Such electromagnetic radiation signals can include, for example, a near-filed communication (NFC) signal, a Bluetooth signal, or any other type of electromagnetic radiation signal. The overlay film can be an optically clear sheet of film, and can include a printed surface. The overlay film can be positioned over the external surface of the top diffusion film 201.

The PCB 209 can include a controller that can monitor voltage signals produced by the voltage sensors and provide power controls to the electronic components (e.g., the light sources, the solar panel 207, etc.) of the solar sign. The controller can include at least one processor and a memory (e.g., a processing circuit, etc.). The memory can store processor-executable instructions that, when executed by processor, cause the processor to perform one or more of the operations described herein. The processor can include a microprocessor, an application-specific integrated circuit (ASIC), a field-programmable gate array (FPGA), etc., or combinations thereof. The memory can include, but is not limited to, electronic, optical, magnetic, or any other storage or transmission device capable of providing the processor with program instructions. The memory can further include a memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor can read instructions. The instructions can include code from any suitable computer programming language.

The processor of the electronics module can receive signals (e.g., via an interconnect or other communications bus, etc.) from the voltage sensors on the PCB 209 that correspond to the amount of light being received by the solar panel 207. Based on the mount of light received from the solar panel 207, the processor can provide signals to one or more switches (e.g., transistors, integrated circuits, etc.) that cause the battery 206 to provide electric power to the light sources connected to the PCB 209. For example, if the processor detects that the amount of voltage produced by the solar panel 207 has fallen below a predetermined threshold, the processor can determine that the solar sign is not properly or completely illuminated. Based on the signals from the voltage sensors, the processor can determine whether the amount of light striking the solar panel 207 represents a temporary blockage (e.g., an external light source is obscured temporarily, etc.), of the amount of light striking the solar panel 207 represents that the solar sign is now in a dark environment (e.g., it is now night time, or the solar sign has been moved to a dark room, etc.). The processor can compensate for the low light levels by transitioning form an unilluminated (e.g., the light source is not receiving power, etc.) state to an illuminated (e.g., the light source is receiving power, etc.) state. The processor can provide (e.g., via the power circuitry, transistors, switches, etc.) an amount of power that is proportional to the amount of light required to illuminate the solar sign. In some implementations, the processor can store information about the amount and the color of one or more graphical designs or printed images printed on the outer surface of the outer diffusion film 8. For darker images with more ink, the processor can provide more electric power to the light sources, thus providing more light to illuminate the darker graphic. Likewise, if a graphic on the solar sign is absent, or has light or small amounts of ink, the processor can provide slightly less electric power to the, thus providing uniform illumination for the solar sign.

The filler 208 can fill the empty space between the other components in the layer formed by the battery 206, the solar panel 207, and the PCB 209. As shown, each of the battery 206, the solar panel 207, and the PCB 209 can be sized such that each has a similar thickness, and fit together on a single layer or plane. However, in some cases, additional space between the battery 206, the solar panel 207, the PCB 209, and the edges of the sheet (e.g., defined by the rails 212 or other edge pieces (not pictured), etc.). The filler 208 can be sized to fill in the gaps formed between the battery 206, the solar panel 207, and the PCB 209 to complete a flat structural layer on top of the back plate 210. The filler 208 can be formed from any suitable non-conductive material, such as plastic, foam, or any other type of filler material. The filler 208 can have substantially similar (e.g., plus or minus 10%) thickness to the battery 206, the solar panel 207, and the PCB 209. Thus, the filler 208 can be used to form a complete layer with the battery 206, the solar panel 207, and the PCB 209 across the entire back plate 210. In some implementations, in addition or as a part of the filler 208, a board with cutouts to hold components, including the PCB 209 (e.g., and any electronics forming a part of the PCB 209, etc.). The board can be manufactured from any suitable material, such as a corrugated plastic material. The board can have a surface color that is similar to the surface color of the solar panel 207. In some implementations, an additional colored film can be positioned on this layer above the PCB 209, the battery 206, or the filler 208, or any combination thereof. The colored film can have a similar color to that of the solar panel 207.

The next layer in the stack can be formed from the light guide 205. The light guide 205 can be similar to and include any of the functional or structural features of the light guide 205 described herein in connection with FIGS. 1A and 1B. The light guide 205 can be positioned adjacent to the solar panel 207, such that light passing through the light guide 205 can strike the solar panel 207 and generate electric power. The light guide 205 can be a transparent plate of material that can both receive and guide light from one or more light sources, such as the light sources on the PCB 209 or an external light source, such as the sun. As described herein, the surface of the light guide 205 (e.g., the surface coupled to the inner diffusion film 204, etc.) can include one or more light extraction features, such as lenses or lenslets. In some implementations, the surface of the light guide 205 opposite the surface coupled to the inner diffusion film 204 can include one or more light exaction features. The light extraction features can extract a portion of the light injected into the light guide 205, such as the light emitted by the light sources on the PCB 209. The light guide 205 can guide another portion of the light injected into the light guide towards an opposite edge of the light guide 205. The light extraction features can be precisely placed across the surface of the light guide 205 in a predetermined pattern, such that light is uniformly extracted, and thus emitted, across the entire surface of the light guide 205. Thus, the light guide 205 can uniformly illuminate the other layers of the solar sign (e.g., the inner diffusion film 204, the top diffusion film 201, etc.), including any graphical designed printed on the outer diffusion film.

The light guide 205 can be optically coupled to the light sources in the solar sign. In some implementations, the light sources can be positioned within a cavity formed in the light guide 205. In some implementations, the cavity can be a hole in the light guide 205 into which the one or more light sources are inserted. The light source can have a thickness that is similar to or less than the thickness of the light guide 205. The light source can emit light through the cavity and into the body of the light guide 205, thereby injecting light into the light guide 205. In some implementations, the light guide 205 does not include a cavity, and instead is a uniform rectangular plate that can receive light emitted from the light source via an edge of the light guide 205. In such implementations, the light sources can be positioned external to the light guide 205 and inject light into the light guide plate via the edge.

The next layer in the solar sign can be formed from the inner diffusion film 204. The inner diffusion film 204 can be similar to and include any of the functional and structural features of the inner diffusion film 6 described herein in connection with FIGS. 1A and 1B. The inner diffusion film 204 can be a sheet of partially transparent film that has a first surface coupled to a border 203 and the spacer 202 (e.g., which can be a transparent plastic spacer, for example, to achieve a desired structural thickness, etc.), and a second surface that is coupled to the light guide 205. The inner diffusion film 204 can be a partially transparent film that appears white, or another solid color, while still allowing an amount of light to pass through the diffusion film and into the light guide 205. For example, light emitted by an external light source (e.g., the sun, etc.) can pass through both the top diffusion film 201, the spacer 202, and the inner diffusion film 204, striking the solar panel 207 where it is absorbed. The inner diffusion film 204 can be uniformly illuminated by the light extracted by the light extraction features of light guide 205, such that the solar sign and any graphical designs printed thereon can be illuminated in low-light environments (e.g., at night time, etc.). In some implementations, the inner diffusion film 204 can have greater than 70% angular diffusion. In some implementations, the inner diffusion film 204 can have a light transmission rate that exceeds 80%. The inner diffusion film can aid in the operation of the light guide 205, which in some implementations can provide a more uniformly distributed light pattern when exposed to air. The inner diffusion film 204 can have a rough surface, and thus when coupled to the light guide 205, the majority of the surface of the light guide 205 is exposed directly to air, because the rough surface of the inner diffusion film 204 is not uniform or perfectly flat.

The next layer in the solar sign can be formed from the border 203 and the spacer 202. The border 203 can provide a weather-proof border for the exposed edges of the solar sign, while surrounding the spacer 202. The spacer 202 can be positioned in the large opening of the border 203, and the spacer 202 and the border 203 can each be coupled to the inner diffusion film 204, described herein above. The border 203 can be manufactured from any suitable material, such as a plastic, rubber, metal, or composite material. In some implementations, the border 203 can be opaque. The spacer 202 can be a thin, flat portion of plastic that acts as a buffer between the inner diffusion film 204 and the top diffusion film 201. The spacer 202 can be manufactured from a transparent material, such as glass, a transparent acrylic, or another type of transparent plastic. The spacer 202 can have dimensions smaller than the inner diffusion film 204, such that the spacer 202 can fit snugly in the large opening of the border 203. Together, the spacer 202 and the border 203 can form a single layer having similar dimensions to the light guide 205. The spacer 202 can have a thickness similar to the thickness of the border 203. The spacer 202 can have high transmissivity, such that light easily passes through the spacer 202. The spacer 202 can allow light diffused from the inner diffusion film 204 to pass largely uninterrupted to the top diffusion film 201, thereby illuminating the solar sign. Likewise, the spacer 202 can receive light from an external light source (e.g., the sun, etc.) via the top diffusion film 201, and allow the light to pass largely uninterrupted through the inner diffusion film 204, striking the solar panel 207.

The top layer of the printable solar sheet can be formed from the top diffusion film 201. The top diffusion film 201 can include any of the functional or structural features of the outer diffusion film 8 described herein in connection with FIGS. 1A and 1B. The top diffusion film 201 can be a sheet of partially transparent film that has a first surface exposed to an external environment and a second surface that is coupled to the spacer 202 and the border 203. The top diffusion film 201 can include a light-turning imprinted surface (e.g., the surface facing the external environment, etc.). The top diffusion film 201 can include a partially transparent surface that appears white, or another solid color, while still allowing an amount of light to pass through the diffusion film and into the light guide 205. Light from an external light source (e.g., the sun, etc.) can pass through the top diffusion film 201, the spacer 202, the inner diffusion film 204, and the light guide 205, striking the solar panel 207 where it is absorbed. The top diffusion film 201 can be a printable film. The top diffusion film 201 can be made from a material to which printer ink can be directly applied. Thus, in some implementations, the solar sign (e.g., including the stack of one or more of the layers shown in FIG. 2A, etc.) can be passed through a printer, such as a wide format inkjet printer, which can print ink directly onto the top diffusion film 201 of the solar sign. The solar sign can be placed on or coupled to a template that guides the solar sign through the printer to facilitate the printing process.

The top diffusion film 201 can be printed on using a latex ink, a colored latex ink, a black ink, a white ink, or any other semi-transparent ink. The top diffusion film 201 can be uniformly illuminated by the light extracted by the light extraction features of light guide 205, such that the solar sign and any graphical designs printed thereon can be illuminated in low-light environments (e.g., at night time, etc.). In some implementations, and as described herein above, the top diffusion film 201 can be coupled to an overlay film such that the illuminated top diffusion film 201 provides uniform illumination through the overlay film. In some implementations, the top diffusion film 201 can be easily removable and replaceable. Thus, different designs for the solar sign can easily be changed by exchanging the top diffusion films 201 having different designs printed thereon.

Referring now to FIG. 2B, illustrated is a cross-sectional view 200B of the example printable solar sign sheet of FIG. 2A, in accordance with one or more implementations. As shown in the view 200B, each of the layers in the solar sign can be pressed against one another firmly, such that they are fixed in place in the base 1 of the solar sign. Also as shown, each of the components can fit within a housing or sheet structure, formed from the rails 212 (e.g., defining the edges of the sheet, etc.), the corner pieces 213 (e.g., defining the corners of the sheet, etc.), and the back plate 210 (e.g., forming the back of the sheet). To enhance weather-proofing and aesthetic appearance, a sheet of the vinyl 211 can cover any gaps formed between the corner pieces 213, the rails 212, and the back plate 210.

The components forming the layers of the solar sign can sit within the base formed from the back plate 210, the rails 212, and the corner pieces 213. In some implementations, an adhesive can be disposed between one or more of the layers of the solar sign. In some implementations, the adhesive can be an optically transparent adhesive with a similar index of refraction to other components of the solar sign (e.g., the light guide 205, etc.). Each of the components of the solar sign can be placed in the base in a particular order. As shown, the base can form a housing for the sign. In some implementations, the base can include one or more attachment or guiding features (e.g., grooves, slots, etc.) into which the other components of the solar sign can fit or connect.

The battery 206, the solar panel 207, the PCB 209, and the filler 208 (not pictured) can first be positioned near the bottom of the base, and can form the first layer of the printable solar sign. In some implementations, the battery 206 can fit into one or more slots, grooves, or recessed portions of the solar sign. The solar panel 207 and the PCB 209 can be positioned adjacent to the battery 206 such that the battery 206, the solar panel 207, the PCB 209, and the filler 208 (not pictured) form a single layer having a relatively uniform thickness across the entire surface of the back plate 210. The PCB 209 can be positioned such that any light sources present on the PCB 209 will be aligned with the light guide 205 when the light guide 205 is positioned in the solar sign. The light guide 205 can be positioned on top of the first layer formed from the battery 206, the solar panel 207, the PCB 209, and the filler 208 in the solar sign. Light passing through the light guide 205 from an external light source can be passed to the surface of the solar panel 207. Further, the light guide 205 can be positioned in the solar sign such that a portion of the light guide 205 can receive light from a light source, such as a light source positioned on or electrically coupled to the PCB 209. In some implementations, the light source can be electrically coupled to but physically separate from the PCB 209 (e.g., on a separate circuit board module, etc.).

The inner diffusion film 204 can be positioned on top of the light guide 205, such that the light emitted from the light sources and extracted by the light extraction features on the surface of the light guide 205 is diffused through the inner diffusion film 204, thereby evenly illuminating the solar sign. The spacer 202 and the border 203 form another internal layer on top of the inner diffusion film 204. As shown, the spacer 202 can have a similar thickness to the border 203, and provide a buffer through which light from the top diffusion film 201 can pass before reaching the inner diffusion film 204. The final layer formed from the top diffusion film 201 can be positioned on top of the layer formed from the spacer 202 and the border 203. As described herein above, the top diffusion film 201 can include a printable surface exposed to the external environment. Inks such as latex inks, or other types of inks, can be printed directly onto the printable surface of the top diffusion film 201. In some implementations, the top diffusion film 201 can create weather-proof seal between the border 203 and the top diffusion film 201, thereby creating a weather-proof, printable sign. It should be understood that the various signs described herein can be scaled to any appropriate dimension, and the entire sign as pictured in FIGS. 2A and 2B can have a profile passable through a printer such that the printer can print on the top diffusion film 201.

Referring briefly now to FIG. 2C, illustrated is a front view of the example printable solar sign sheet shown in FIGS. 2A and 2B, in accordance with one or more implementations. As shown, when fully assembled, the solar sign can resemble a regular sign. Graphical designs can be printed directly onto the surface of the top diffusion film 201, and the area in the center portion (e.g., within the region defined by the opening in the border, etc.) can be illuminated in low-light conditions. The solar sign can be thin enough to be used directly as a print media. FIG. 2D illustrates a side view of the example printable solar sign, showing that the sign itself, when assembled, can be thin enough to be fed directly into a printer. Thus, the solar signs here can be used directly as an opto-electronic print media that is self-contained, weather-proof, and includes automatic control circuitry that controls sign illumination and charging. In some implementations, one or more brackets (not pictured) can be coupled to or form a part of the back plate 210, the rails 212, or the corner pieces 213. The brackets can allow the sign to be mounted to one or more frames, such as an A-frame, that allows the sign to be positioned at an angle that appears upright, but is at a slight angle to absorb optimal amounts of light from external light sources.

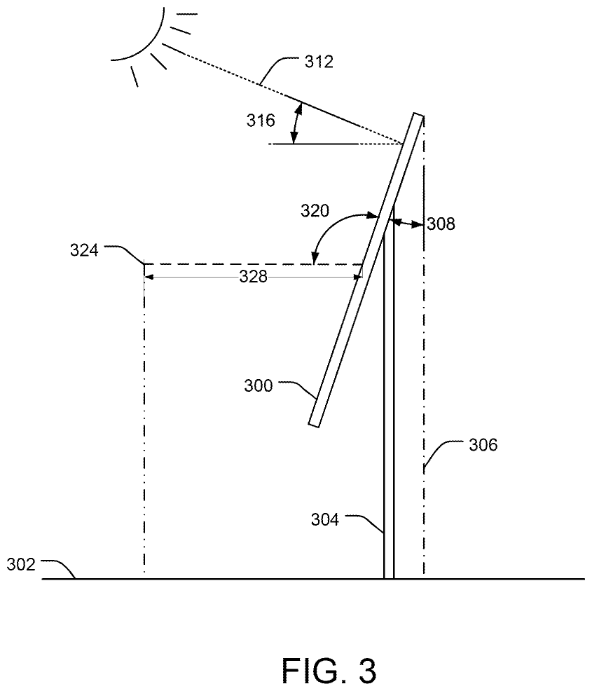

Referring now to FIG. 3, illustrated is a schematic diagram of an example sign 300 mounted to ground 302 using a mount 304, in accordance with one or more implementations. The sign 300 can incorporate features of various signs described herein, such as the solar sign described with reference to FIGS. 1A-1B and the printable solar sign sheet described with reference to FIGS. 2A-2D. For example, the sign 300 can include one or more layers, such as solar panel or film, electronics, light guide, and diffusion film layers.

The sign 300 can include the diffusion film (e.g., the diffusion film on which ink has been printed). The sign 300 can be film-ready. For example, the sign 300 can be coupled with the mount 304 as a module, and can receive the diffusion film (e.g., the diffusion film on which ink has been printed). For example, at least one of the sign 300 or the mount 304 can include or be provided with at least one of an adhesive or a receiving member (e.g., bracket, clip) that can receive the diffusion film to position the diffusion film on the sign 300.

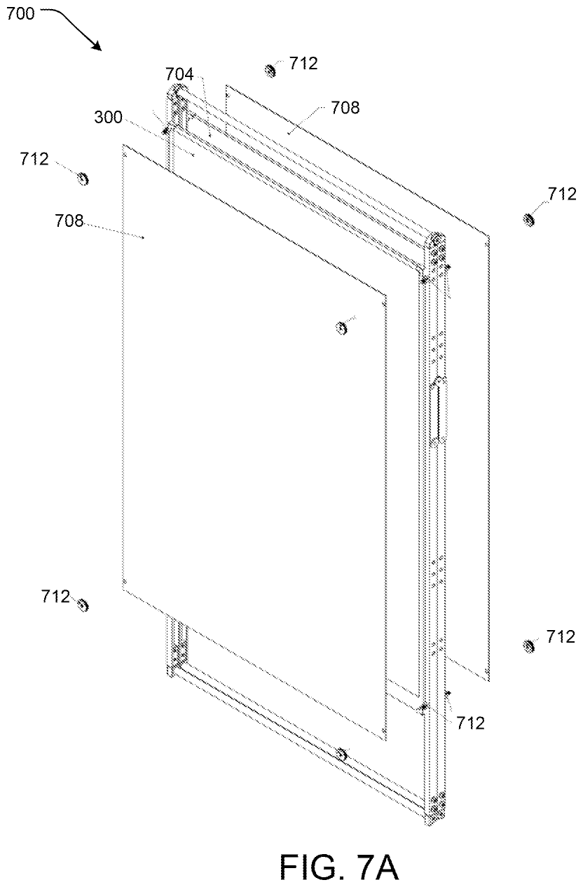

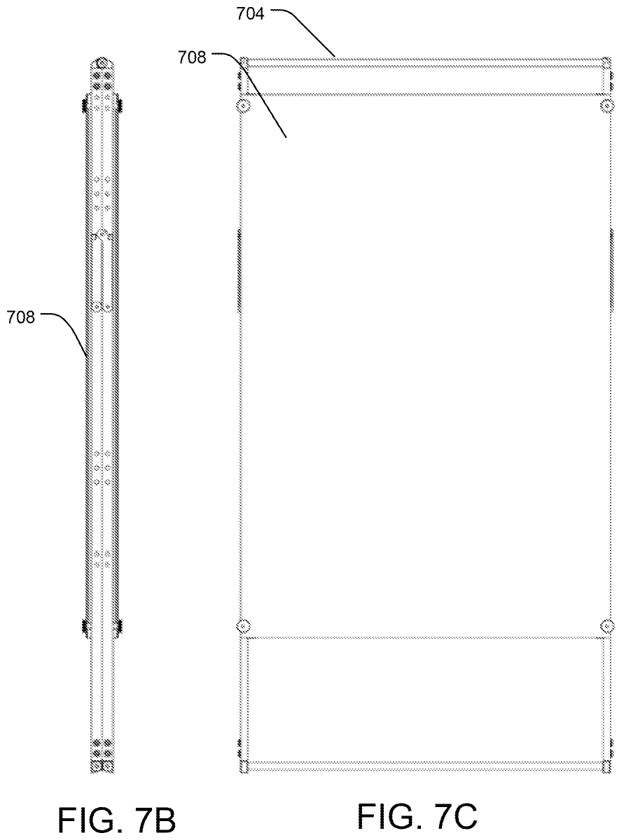

The diffusion film can be replaceably (e.g., removably) positioned on the sign 300. For example, the diffusion film can be an overlay that can be printed (e.g., as described with respect to top diffusion film 201), and placed as an overlay in the receiving member, or coupled using fasteners (e.g., as described with respect to overlays 708 of FIGS. 7A-7C). As such, various designs can be printed on various diffusion films, which can be replaceably coupled with (e.g., swapped in and out of) the sign 300.

The mount 304 can be implemented using various mounting components, such as A-frames, universal mounts, posts (e.g., metal posts that can be driven into the ground using a tool such as a hammer), attachment clips, and screws, such as to implement the sign 300 as a yard sign, wall sign, fence sign, or vehicle sign, including at non-vertical angles. The mount 304 can allow for replacement of one or more signs 300, and can enable portability of the signs 300.

The mount 304 can orient (e.g., tilt) the sign 300 at an angle 308 relative to an axis 306 perpendicular (e.g., normal) to the ground 302. Due to the orientation of the sign 300 at the angle 308, the sign 300 can receive one or more rays 312 of solar energy from the sun at an angle 316. As depicted in FIG. 3, the angle 316 can be defined between the (perpendicular) intersection of the ray 312 with the sign 300 and a plane 318 parallel with the ground 302; various angles, such as tilt angles, incidence angles, inclination angles, azimuth angles, and elevation angles, among others, can be used to characterize the orientation of the sign 300 relative to the ray 312 and the ground 302.

Due to the interaction of the ray 312 with the solar panel or film of the sign 300, an amount of solar energy received by the sign 300 can correspond to at least one of the angle 308 or the angle 316. For example, increasing the angle 308 away from the axis 306, at least up to a certain point, can increase the efficiency of solar energy reception and storage by the sign 300, and thus increase the ability of the sign 300 to store sufficient energy to reliably light up at night.

The sign 300 can define an angle 320 relative to a point 324, which can be defined at a distance 328 from the sign 300. The distance 328 can correspond to a target viewing range for the sign 300, such as a range at which a viewer is to perceive the sign 300. For example, the distance 328 can be less than 100 feet. The distance 328 can be greater than 10 feet and less than 50 feet. The distance 328 can be proportional to a surface area of the sign 300.

The sign 300 can have viewing criteria, which can be determined relative to the point 300. For example, the sign 300 can define a verticality criteria. For example, although the sign 300 is tilted by the angle 308 (or the angle 320), for relatively low values of the angle 308, the sign 300 can appear to be vertical at the point 324. The verticality can correspond to factors such as a distance of the top of the sign 300 relative to the bottom of the sign 300 from the point 324 (e.g., as the angle 308 increases, the top of the sign 300 will be further from the point 324 than the bottom, and thus can appear to be narrower than an actual length of the top of the sign 300 relative to an actual length of the bottom of the sign 300). As such, the verticality criteria can include a ratio of a distance from the point 324 to the top of the sign 300 and to the bottom of the sign 300, such that the sign 300 can appear to be vertical based on the ratio being greater than a threshold ratio, which can correspond to the angles 308, 320.

As described above with reference to FIGS. 1A-2D, the sign 300 can be printable, and thus can have information presented on the sign 300 using ink or other printing materials. The verticality criteria can correspond to a maximum threshold for the angles 308, 320 for presentation of the information. For example, similar to the distances of the top and bottom of the sign 300 relative to the point 324, if ink is used to present text information as characters, the text information should appear to be of a similar size whether closer to the top or bottom of the sign 300 (scaling for an actual size of the text as printed), and should not appear wider towards the bottom of the text characters relative to the top of the text characters. The verticality criteria can correspond to a range of angles 308 (or 320) so that the information presented on the sign 300 appears vertical both during the day (e.g., when the information is perceived based on interaction of the rays 312 with the information, such as reflection of the rays 312 by the ink used to present the information) and night (e.g., when the information is perceived based on light output from the LEDs of the sign 300, such as light output from the LEDs through the ink).

As such, the mount 304 can be configured to orient the sign 300 so that the angle 308 is greater than or equal to a first value corresponding to a minimum amount of solar energy from the rays 312 to be received through a diffusion film of the sign 300 by a solar panel or film of the sign 300 and less than or equal to a second value so that the sign 300 satisfies a verticality criteria. The mount 304 can be configured to tilt the sign 300 no more than a predetermined range from vertical (e.g., from the axis 306).

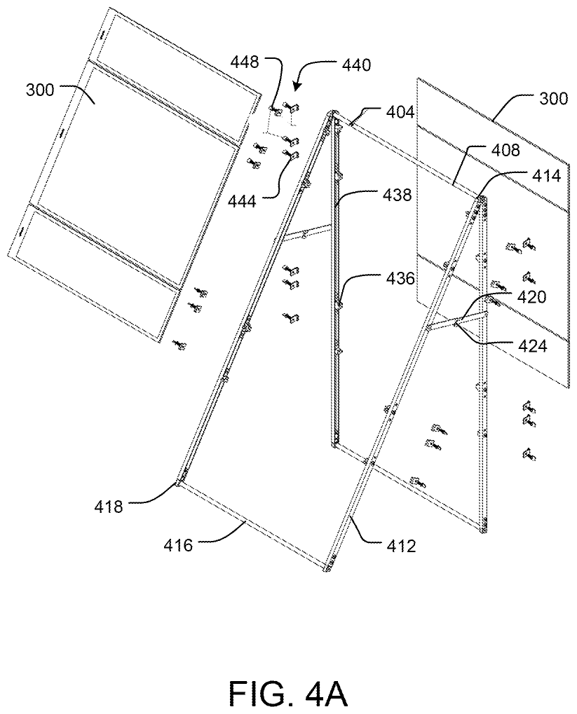

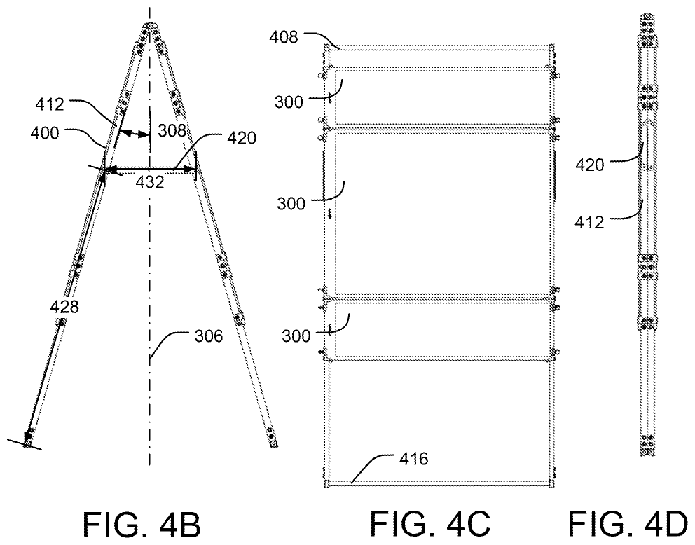

Referring now to FIGS. 4A-4D, illustrated is an example solar sign assembly 400, in accordance with one or more implementations. The solar sign assembly 400 can include one or more signs 300 received by a frame 404. The signs 300 can be received as a unitary module. One or more layers of the signs 300 can be received by the frame 404, and an overlay (e.g., the diffusion film printed with ink) can be overlaid on the one or more layers. As illustrated in FIGS. 4A-4D, the frame 404 can receive multiple signs 300 of various sizes.

The frame 404 can be implemented as an A-frame. The frame 404 can include a first beam 408, which can extend laterally relative to an orientation of the signs 300. For example, the first beam 408 can correspond to a top of the solar sign assembly 400.

The frame 404 can include a plurality of second beams 412 that are coupled to ends 414 of the first beam 408, and can extend traverse to the first beam 408 to a plurality of third beams 416 having ends 418 coupled with the second beams 412 opposite the first beam 408. The third beams 416 can be parallel with the first beam 408. The third beams 416 can define a bottom of the solar sign assembly 400.

The frame 404 can include a plurality of adjustment members 420 coupled with respective second beams 412. The adjustment members 420 can include a pivot 424, such as a hinge, to allow the frame 404 to be manipulated between a first state (e.g., as depicted in FIGS. 4 and 4B) and a second state (e.g., as depicted in FIG. 4D).

The adjustment members 420 can be at least one of positioned along the second beams 412 and sized to orient the signs 300 to satisfy the verticality criteria described with reference to FIG. 3. For example, as illustrated in FIG. 4B, the adjustment members 420 can be coupled with the second beams 412 at a distance 428 from the first beam 408 (or a corresponding distance from the third beam 416) and have a length 432 (e.g., while fully extended), such that the sign 300 is oriented at the angle 308. As illustrated in FIG. 4D, the adjustment members 420 can be adjusted to be parallel with one another and the second beams 412 where the frame 404 is in the second state.

The frame 404 can include a plurality of receivers 436. The receivers 436 can be used to receive the signs 300, such as to couple with fasteners 440. The fasteners 440 can include components such as clips 444 (e.g., retention clips) and screws 448. The receivers 436 can be slidingly coupled with tracks 438 defined in the second beams 412, allowing for signs 300 of various sizes to be received by the frame 404 and positioned in various positions relative to the frame 404.

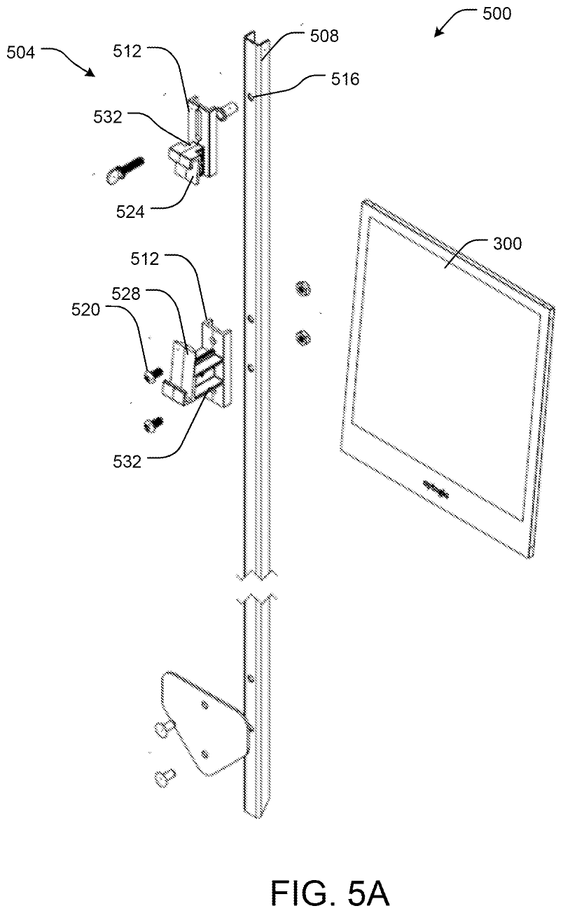

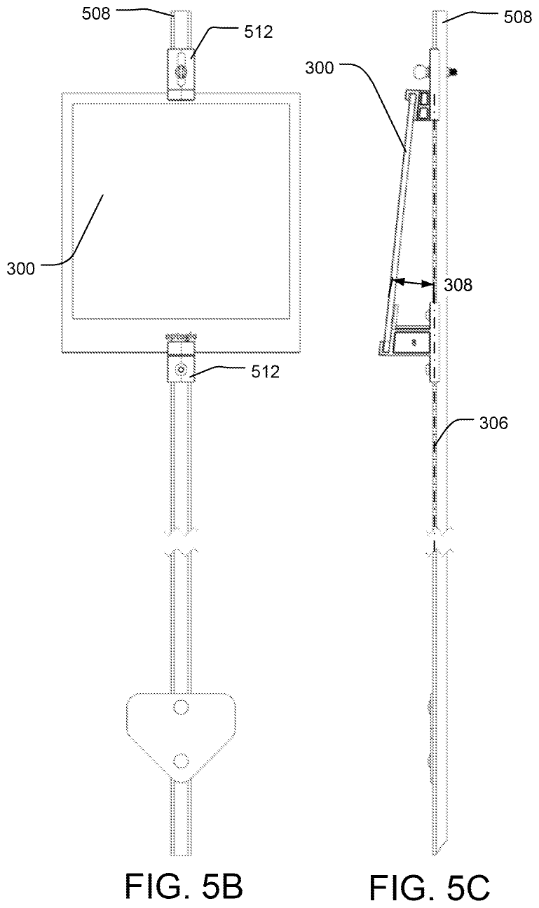

Referring now to FIGS. 5A-5C, illustrated is an example solar sign assembly 500, in accordance with one or more implementations. The solar sign assembly 500 can include one or more of the signs 300, which can be installed with a mount 504. The mount 504 can be used to orient the sign 300 to satisfy various verticality criteria as described with reference to FIG. 3.

The mount 504 can include a post 508. The post 508 can be made from metal The post 508 can have sufficient rigidity to be driven into ground (e.g., terra firma) or supported by ground materials such as concrete or asphalt. For example, the post 508 can be driven into ground using a hammer.

The post 508 can couple with one or more receivers 512. For example, the post 508 can define one or more openings 516 that the receivers 512 can be positioned adjacent to and be fixed to the post 508 using fasteners 520. The sign 300 can be replaceably slid into and out of the receivers 512.

The receivers 512 can orient the sign 300 at the angle 308 to satisfy verticality criteria for the sign 300. For example, the receivers 512 can include a first receiver 512 having a first receiving surface 524, and a second receiver 512 having a second receiving surface 528. The receiving surfaces 524, 528 can be oriented at the angle 308 to orient the sign 300 at the angle 308. The receivers 512 can include beams 532 that position the receiving surfaces 524, 528 to be in a same plane, such that the sign 300 can lie flat against both receiving surfaces 524, 528.

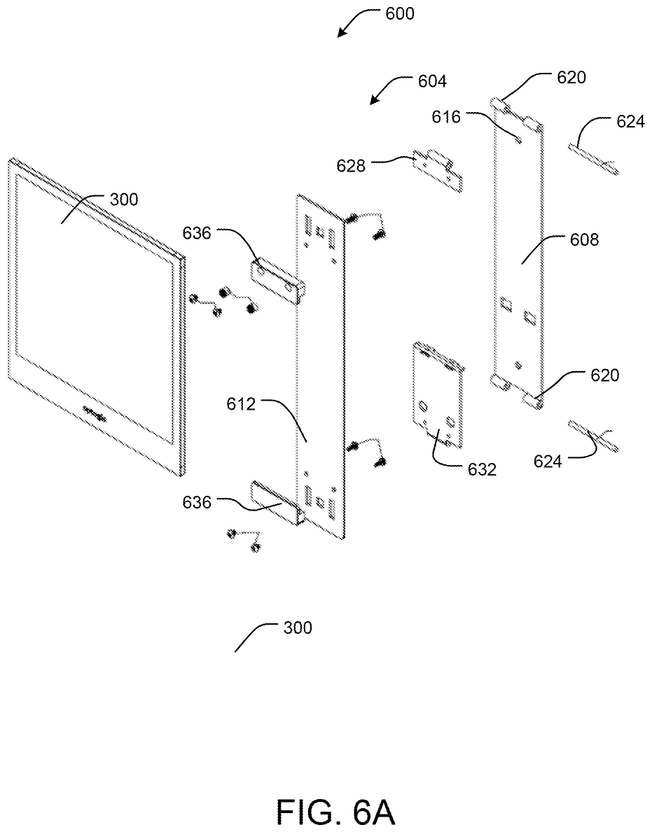

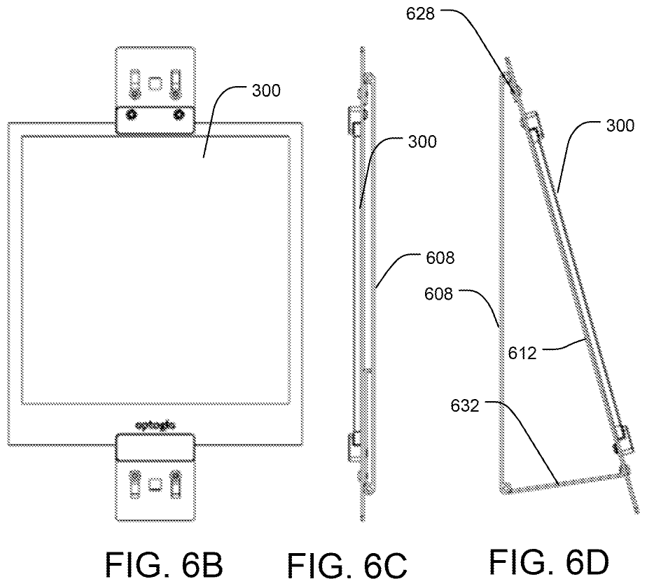

Referring now to FIGS. 6A-6D, illustrated is a solar sign assembly 600, according to one or more implementations. The solar sign assembly 600 can include one or more signs 300, which can be installed with a mount 604 (e.g., universal mount). The mount 604 can be used to orient the sign 300 to satisfy various verticality criteria described with reference to FIG. 3, including to mount the sign 300 to surfaces of components such as walls of buildings or vehicles.

The mount 604 can include a wall plate 608 and a mounting plate 612. The wall plate 608 can include at least one opening 616 to receive a fastener for coupling the wall plate 608 with a wall.

The wall plate 608 can include channels 620 to receive pins 624 (e.g., hinge pins). The channels 620 can be positioned at respective top and bottom ends of the wall plate 608 to pivotably connect with a respective first flange 628 and second flange 632. For example, the flanges 628, 632 can couple with the pins 624 to rotate relative to the channels 620.

The mounting plate 612 can be coupled with the flanges 628, 632 to be pivotably coupled with the wall plate 608. The second flange 632 can be longer than the first flange 628 to allow for orienting the sign 300, which is received by the wall plate 608 by receivers 636, at the angle 308. For example, the flanges 628, 632 can be pivot relative to the wall plate 608 to allow the mounting plate 612 to be shifted from a first state in which the mounting plate 612 is relatively close to the wall plate 608, such as parallel with the wall plate 608 as illustrated in FIG. 6C, to a second state, such as for orienting the sign 300 at the angle 308 as illustrated in FIG. 6D.

Referring now to FIGS. 7A-7C, illustrated is an example of a solar sign assembly 700, according to one or more implementations. The solar sign assembly 700 can include one or more signs 300 coupled with a mount 704, and one or more overlays 708, such as artwork overlays, which can be replaceably received by the mount 704. For example, the mount 704 can incorporate features of the frame 404 described with reference to FIGS. 4A-4D for receiving the signs 300. The mount 704 can include one or more fasteners 712, such as threaded studs and thumb nuts, to secure the mount 704 with the overlays 708.

While operations are depicted in the drawings in a particular order, such operations are not required to be performed in the particular order shown or in sequential order, and all illustrated operations are not required to be performed. Actions described herein can be performed in a different order.

The separation of various system components does not require separation in all implementations, and the described program components can be included in a single hardware or software product.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed in connection with one implementation are not intended to be excluded from a similar role in other implementations.

The phraseology and terminology used herein is for the purpose of description and should not be regarded as limiting. The use of “including”, “comprising”, “having”, “containing”, “involving”, “characterized by”, “characterized in that”, and variations thereof herein is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

As used herein, the terms “about” and “substantially” will be understood by persons of ordinary skill in the art and will vary to some extent depending upon the context in which they are used. If there are uses of the term which are not clear to persons of ordinary skill in the art given the context in which it is used, “about” will mean up to plus or minus 10% of the particular term.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation or embodiment, and references to “an implementation,” “some implementations,” “one implementation,” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

The indefinite articles “a” and “an,” as used herein in the specification and in the claims, unless clearly indicated to the contrary, should be understood to mean “at least one.”

References to “or” may be construed as inclusive so that any terms described using “or” may indicate any of a single, more than one, and all the described terms. For example, a reference to “at least one of ‘A’ and ‘B’ can include only ‘A’, only ‘B’, as well as both ‘A’ and ‘B’. Such references used in conjunction with “comprising” or other open terminology can include additional items.

Where technical features in the drawings, detailed description, or any claim are followed by reference signs, the reference signs have been included to increase the intelligibility of the drawings, detailed description, and claims. Accordingly, neither the reference signs nor their absence has any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

What is claimed is:

1. A solar sign assembly, comprising:
a backlight, comprising:
a light guide; and
a solar panel coupled to the light guide, the solar panel receives light through the light guide;
a printable diffusion film placeable on the backlight; and
a mount configured to orient the backlight at an angle relative to ground, the angle is (1) greater than or equal to a first value corresponding to a minimum amount of solar energy from the light received by the solar panel through the diffusion film and the light guide and (2) less than or equal to a second value at which an appearance of information printed on the diffusion film satisfies a criteria of verticality.

2. The solar sign assembly of claim 1, wherein the mount comprises a plurality of beams configured to receive the backlight and orient the backlight at the angle.

3. The solar sign assembly of claim 1, wherein the criteria of verticality corresponds to a first distance from a top of backlight to a point facing the backlight and a second distance from a bottom of the backlight to the point.

4. The solar sign assembly of claim 1, comprising at least one receiver that slidably receives the backlight.

5. The solar sign assembly of claim 1, wherein the mount comprises a metal post.

6. The solar sign assembly of claim 1, wherein the mount comprises a first plate configured to be attached to a wall, a second plate configured to receive the backlight, and a plurality of flanges configured to orient the second plate at the angle.

7. The solar sign assembly of claim 1, wherein the mount comprises at least one of an A-frame, a post, a universal mount, or an artwork frame.

8. The solar sign assembly of claim 1, wherein the mount is configured to orient the sign at the angle in a first state, and orient the sign to be vertical in a second state.

9. A solar sign frame, comprising:
a solar-powered light panel;
a printable diffusion film placeable on the light panel; and
a mount configured to orient the backlight at no more than a predetermined angle relative to vertical.

10. The solar sign frame of claim 9, wherein the mount comprises a plurality of beams configured to receive the light panel and orient the light panel at the angle.

11. The solar sign frame of claim 9, comprising at least one receiver that slidably receives the light panel.

12. The solar sign frame of claim 9, wherein the mount comprises a metal post configured to be driven into a ground surface.

13. The solar sign frame of claim 9, wherein the mount comprises a first plate configured to be attached to a wall, a second plate configured to receive the backlight, and a plurality of flanges configured to orient the second plate at the angle.

14. The solar sign frame of claim 9, wherein the mount comprises at least one of an A-frame, a post, a universal mount, or an artwork frame.

15. A portable solar-powered sign, comprising:
a backlight, comprising:
a light guide; and
a solar panel coupled to the light guide, the solar panel receives light through the light guide;
a diffusion film having printed ink and placeable on the backlight; and
a mount configured to orient the backlight at an angle relative to ground such that a visibility of the diffusion film satisfies a visibility criteria during a day condition and a night condition and an amount solar energy received during the day condition satisfies a solar energy criteria.

16. The portable solar-powered sign of claim 15, wherein the mount comprises a plurality of beams configured to receive the light panel and orient the light panel at the angle.

17. The portable solar-powered sign of claim 15, comprising at least one receiver that slidably receives the light panel.

18. The portable solar-powered sign of claim 15, wherein the mount comprises a metal post.

19. The portable solar-powered sign of claim 15, wherein the mount comprises a first plate configured to be attached to a wall, a second plate configured to receive the backlight, and a plurality of flanges configured to orient the second plate at the angle.

20. The portable solar-powered sign of claim 15, wherein the mount comprises at least one of an A-frame, a post, a universal mount, or an artwork frame.
